(19) United States
(12) Patent Application Publication
(10) Pub. No.: US 2026/0276768 A1
(43) Pub. Date: Sep. 17, 2026

(54) SYSTEMS AND METHODS FOR NUCLEAR MAGNETIC RESONANCE SPECTROSCOPY

(71) Applicant: PRESIDENT AND FELLOWS OF HARVARD COLLEGE, Cambridge, MA (US)

(72) Inventors: Yiqiao Song, Cambridge, MA (US); Guang Yang, Cambridge, MA (US); Behdad Aghelnejad, Cambridge, MA (US); Donhee Ham, Cambridge, MA (US)

(73) Assignee: PRESIDENT AND FELLOWS OF HARVARD COLLEGE, Cambridge, MA (US)

(21) Appl. No.: 19/470,795

(22) PCT Filed: Mar. 29, 2024
(86) PCT No.: PCT/US2024/022266

§ 371 Date: Sep. 29, 2025

Related U.S. Application Data
(60) Provisional application No. 63/456,412, filed on Mar. 31, 2023.

(51) Int. Cl. G01R 33/561

(52) U.S. Cl. CPC G01R 33/561

(57) ABSTRACT

A method can include providing first nuclear magnetic resonance (NMR) data. The first NMR data can include a plurality of NMR scans and have a first spectral resolution. The plurality of NMR scans can include a first NMR scan and a second NMR scan. The method can include applying optimization to the plurality of NMR scans to obtain a frequency shift parameter. The frequency shift parameter can include a first frequency shift associated with the first NMR scan and a second frequency shift associated with the second NMR scan. The method can include providing second NMR data. The second NMR data can include the first NMR scan shifted by the first frequency shift and the second NMR scan shifted by the second frequency shift. The second NMR data can have a second spectral resolution greater than the first spectral resolution.

### CROSS-REFERENCE TO RELATED PATENT APPLICATION

This application claims the benefit and priority of U.S. Provisional Patent Application No. 63/456,412, filed on Mar. 31, 2023, the entirety of which is incorporated by reference herein.

### GOVERNMENT RIGHTS

This invention was made with government support under DE-AR0001063 awarded by U.S. Department of Energy (DOE). The government has certain rights in this invention.

### TECHNICAL FIELD

The present application relates generally to nuclear magnetic resonance.

### BACKGROUND

Nuclear Magnetic resonance (NMR) is widely used in many areas of chemical analysis for characterization of materials.

### SUMMARY

At least one aspect of the present disclosure is directed to a method. The method can include providing first nuclear magnetic resonance (NMR) data. The first NMR data can include a plurality of NMR scans and have a first spectral resolution. The plurality of NMR scans can include a first NMR scan and a second NMR scan. The method can include applying optimization to the plurality of NMR scans to obtain a frequency shift parameter (e.g., value/level/extent/indication of frequency shift/change/delta/offset). The frequency shift parameter can include a first frequency shift associated with the first NMR scan and a second frequency shift associated with the second NMR scan. The method can include providing second NMR data. The second NMR data can include the first NMR scan shifted by the first frequency shift and the second NMR scan shifted by the second frequency shift. The second NMR data can have a second spectral resolution greater than the first spectral resolution.

Another aspect of the present disclosure is directed to a non-transitory computer-readable media having computer-readable instructions stored thereon that, when executed by at least one controller, cause the at least one controller to provide first nuclear magnetic resonance data comprising a plurality of NMR scans and having a first spectral resolution, the plurality of NMR scans comprising a first NMR scan and a second NMR scan. The instructions can cause the at least one controller to apply optimization to the plurality of NMR scans to obtain a frequency shift parameter comprising a first frequency shift associated with the first NMR scan and a second frequency shift associated with the second NMR scan. The instructions can cause the at least one controller to provide second NMR data comprising the first NMR scan shifted by the first frequency shift and the second NMR scan shifted by the second frequency shift, the second NMR data having a second spectral resolution greater than the first spectral resolution.

Those skilled in the art will appreciate that the summary is illustrative only and is not intended to be in any way limiting. Other aspects, inventive features, and advantages of the devices and/or processes described herein, as defined solely by the claims, will become apparent in the detailed description set forth herein and taken in conjunction with the accompanying drawings.

### BRIEF DESCRIPTION OF THE DRAWINGS

The details of one or more implementations of the subject matter described in this specification are set forth in the accompanying drawings and the description below. Other features, aspects, and advantages of the subject matter will become apparent from the description, the drawings, and the claims.

FIG. 1A illustrates a single scan of a water sample with a single peak.

FIG. 1B illustrates the spectra of four scans of the water sample acquired over one minute.

FIG. 1C illustrates the spectrum of the sum of sixteen scans of the water sample.

FIG. 1D illustrates the spectrum of the sum of sixteen scans after frequency correction was applied, according to an embodiment.

FIG. 2A illustrates the time-domain signals of FIG. 1A.

FIG. 2B illustrates the time-domain signals of FIG. 1B.

FIG. 2C illustrates the time-domain signals of FIG. 1C.

FIG. 2D illustrates the time-domain signals of FIG. 1D.

FIG. 3A illustrates the spectrum of water after frequency correction was applied, according to an embodiment.

FIG. 3B illustrates the spectrum of water before frequency correction was applied.

FIG. 3C illustrates the spectrum of ethanol after frequency correction was applied, according to an embodiment.

FIG. 3D illustrates the spectrum of ethanol before frequency correction was applied.

FIG. 3E illustrates the spectrum of mineral oil after frequency correction was applied, according to an embodiment.

FIG. 3F illustrates the spectrum of mineral oil before frequency correction was applied.

FIG. 4 illustrates a method of improving NMR spectral resolution, according to an embodiment.

FIG. 5 illustrates a block diagram of an architecture for a computer system that can be employed to implement elements of the systems and methods described and illustrated herein.

Like reference numbers and designations in the various drawings indicate like elements.

### DETAILED DESCRIPTION

Following below are more detailed descriptions of various concepts related to, and implementations of, methods, apparatuses, and systems for improving NMR spectral resolution. The various concepts introduced above and discussed in greater detail below may be implemented in any of a number of ways, as the described concepts are not limited to any particular manner of implementation. Examples of specific implementations and applications are provided primarily for illustrative purposes.

NMR signals can be obtained from NMR spectrometers. NMR spectrometers can include equipment (e.g., hardware) such as magnets to produce a static magnetic field, radiofrequency (RF) electronics to generate pulses of RF magnetic fields, and gradient electronics to produce pulses of direct current (DC) magnetic fields and gradients. The operation of this hardware can produce signals originating from the hydrogen atoms in the samples. The signal can be processed to obtain information about the materials.

The magnetic resonance (MR) phenomenon can include the application of magnetic fields to an object that impacts the magnetic moment (e.g., spin) of an atom in the object. The magnetic field can cause the spin of the atoms in the object to align along and oscillate (e.g., precess) about the axis of the applied magnetic field. The precession frequency can be indicative of the molecular moieties and the molecular structure. The spin magnetization of the atoms can be measured. Relaxation can include the return to equilibrium of this magnetization. For example, longitudinal relaxation due to energy exchange between the spins of the atoms and the surrounding lattice (e.g., spin-lattice relaxation) can be denoted by a time T₁ when the longitudinal magnetization has returned to a predetermined percentage (e.g., 63%) of its final value. Longitudinal relaxation can involve the component of the spin parallel or antiparallel to the direction of the magnetic field. Transverse relaxation that results from spins getting out of phase can be denoted by time T₂ when the transverse magnetization has lost a predetermined percentage (e.g., 63%) of its original value. The transverse relaxation can involve the components of the spins oriented orthogonal to the axis of the applied magnetic field. The T₂ measurement can be performed using the spin-echo pulse sequence, which can involve a 90-degree pulse followed by one 180-degree refocusing pulse. The T₂ can be measured using the Carr-Purcell-Meiboom-Gill (CPMG) pulse sequence, which can use an initial 90-degree excitation pulse followed by a series of 180-degree (pi) pulses.

The NMR signals, frequencies, and relaxation times can be affected by various physical phenomena of the molecular structures and molecular dynamics. The phenomena can include spin-lattice relaxation, spin-spin relaxation, and molecular diffusion of the molecules. Spin-lattice relaxations can be characterized by time constant, T₁. Spin-spin relaxations can be characterized by time constant, T₂. The diffusion can be characterized by the diffusion constant, D. These parameters can be measured using NMR systems based on superconducting magnets. However, these superconducting systems can be large and expensive, thus limiting their broad applications.

Small-size systems based on permanent magnets can perform NMR measurements. However, the magnetic field of such magnets can be sensitive to the magnet temperature. Thus, the frequency of the NMR signal can change as the magnet temperature drifts. As a result, the multiple scans of the NMR signals can appear as a spectral broadening and thus degrade the spectral resolution.

The systems and methods of the present disclosure, in some embodiments, relate to systems and methods to recover the spectral resolution by countering the frequency drift. For example, the methods of the present disclosure can improve NMR spectral resolution by countering the temperature drift of one or more magnets. The methods of the present disclosure can improve the resolution of the NMR spectrum obtained using permanent magnets subject to temperature drift. The systems and methods of the present disclosure, in some embodiments, relate to acquiring NMR signals from an NMR system and applying a mathematical algorithm to remove/reduce/minimize/reverse the broadening effect of the frequency drift to improve the resolution of the NMR spectrum.

NMR properties of materials can include the frequency spectrum, spin-lattice relaxation time (T₁), spin-spin relaxation time (T₂), and diffusion coefficient (D). Each property can be measured by specific pulse sequences and NMR experiments.

A method for obtaining frequency spectrum measurements can include the free-induction-decay method. This method can use the following pulse sequence described in Equation 1:

$$RD - p 90 - ACQ \qquad ( 1 )$$

The first time period RD can be long (e.g., a few seconds, several times of T₁ of the sample) for the system to recover to thermal equilibrium. The p90 pulse can rotate the spin magnetization to the transverse plane to produce an NMR signal to be detected during the time period marked as ACQ. The detected signal can then be Fourier transformed to obtain the frequency spectrum. The frequency axis can be rescaled to chemical shift (CS) which is defined as Equation 2:

$$CS = ( f - {f}_{0} ) / {f}_{0} , \qquad ( 2 )$$

where f is the frequency of the NMR spectrum, and f₀ is the frequency of the reference signal. The reference signal can be determined by the hydrogen NMR frequency of tetramethylsilane (TMS, Si(CH₃)₄). Because the CS can be small, the CS axis can be displayed in ppm (part-per-million).

Different methods can be used to obtain T₁. For example, the T₁ measurement can be obtained using the inversion-recovery (IR) method and saturation-recovery (SR) method. For the IR method, the pulse sequence can be described as Equation 3:

$$RD - p 180 - WT - p 90 - ACQ \qquad ( 3 )$$

Here, the first time period RD can be long (e.g., several times of T₁ of the sample) for the system to recover to thermal equilibrium. The p180 pulse can invert the magnetization. The time WT can allow the magnetization (M) to relax according to Equation 4:

$$M ( WT ) = {M}_{0} \{ 1 - 2 exp [ - \frac{WT}{{T}_{1}} ] \} , \qquad ( 4 )$$

where M₀ is the equilibrium magnetization of the sample. The magnetization can be measured after the data acquisition (ACQ) after the p90 pulse. Several measurements of the signal for a series of values of WT can be obtained to determine the T₁ of the sample.

Furthermore, imaging pulse sequences combining RF pulses and gradient pulses can be applied after the WT in Equation 1 to produce MRI images. In this case, Equation 2 can be applied to each voxel of the image. When several images with different WT are obtained, it is possible to obtain T₁ for each and all voxels in order to obtain a spatial map of T₁ of the sample.

In the SR method, the pulse sequence can be described as Equation 5:

$$WT - p 90 - ACQ \qquad ( 5 )$$

Here it can be assumed that the magnetization at the beginning of the WT period is zero due to the saturation in the previous experiment or by additional pulses to saturate. The magnetization can recover during the time WT according to Equation 6:

$$M ( WT ) = {M}_{0} \{ 1 - exp [ - \frac{WT}{{T}_{1}} ] \} , \qquad ( 6 )$$

Similar to the IR method, the imaging method and pulse sequences can be added to obtain an image of the sample.

For the measurement of T₂, a spin-echo pulse sequence can be used, which can be described in Equation 7:

$$RD - p 90 - TE / 2 - p 180 - TE / 2 - ACQ \qquad ( 7 )$$

Here the time period TE can be defined as echo time. The time spacing between the p90 and p180 is half TE (e.g., TE/2). The magnetization can decay as a function of TE according to Equation 8:

$$M ( TE ) = {M}_{0} exp [ - \frac{TE}{{T}_{2}} ] , \qquad ( 8 )$$

where M₀ is the magnetization when TE/T₂ approaches 0. Similar to the T₁ measurement described above, when several measurements with different TE are obtained, the value of T₂ of a sample can be obtained.

In addition to the spin-echo sequence, the CPMG sequence can be used with multiple p180 pulses to generate a train of echoes. The echo time for echo number n is n*TE. For example, for the first echo, n=1 and for the 10^{th} echo, n=10. As a result, with one experiment, several data points of the signal decay can be obtained and thus accelerate the measurement of T₂.

The property of molecular diffusion can reflect the molecular composition as well as the physical and fluidic environment. For example, when a water molecule is in a viscous fluid, its diffusion coefficient (D) can decrease. When fluid is inside porous materials or tissues, water diffusion can be restricted due to the presence of solid materials or membranes. The diffusion coefficient can be lower than the value in the bulk fluid. As a result, the measurement of the diffusion coefficient can be used to characterize porous materials and tissue microstructure.

Diffusion can be measured using a spin-echo sequence with additional field gradient pulses during the two time periods, first between the p90 and p180 and second between p180 and ACQ. The magnetization decay due to diffusion can be described in Equation 9:

$$M ( b ) = {M}_{0} exp [ - bD ] , \qquad ( 9 )$$

where D is the diffusion coefficient, and b is the diffusion weighting determined by the pulse sequence and in particular the field gradient pulses used. Similar to the T₁ and T₂ measurements, several signals with different b values can be obtained to determine D.

All the measurements described above, including relaxation and diffusion, can be performed by acquiring the NMR spectrum during the data acquisition period (ACQ). Thus, the dynamics of all hydrogen atoms (as represented by the peaks) can be determined. It can be important to achieve a high resolution of the NMR spectrum to identify each peak.

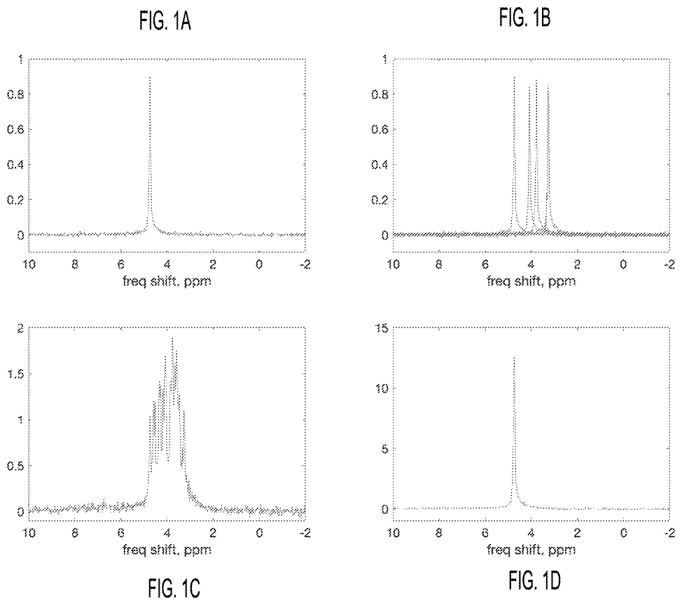

When a permanent magnet is used for NMR data acquisition, the magnetic field can be subject to the ambient temperature change. The frequency of the observed signal can change accordingly (e.g., relative to the ambient temperature change). FIG. 1A illustrates a single scan of a water sample with a single peak. FIG. 1A shows a single scan of the water sample with a single peak. On the subsequent scans over the next minute, the center of the peak drifts to different frequencies as shown in FIG. 1B. FIG. 1B illustrates the spectra of four scans of the water sample acquired over one minute. As a result, the sum/combination of the signals exhibits a very broad spectrum as shown in FIG. 1C. FIG. 1C illustrates the spectrum of the sum of sixteen scans of the water sample. In NMR spectroscopy, multiple scans can be acquired and summed to improve the signal-to-noise ratio. FIG. 1D illustrates the spectrum of the sum of sixteen scans after the frequency correction of the present disclosure was applied.

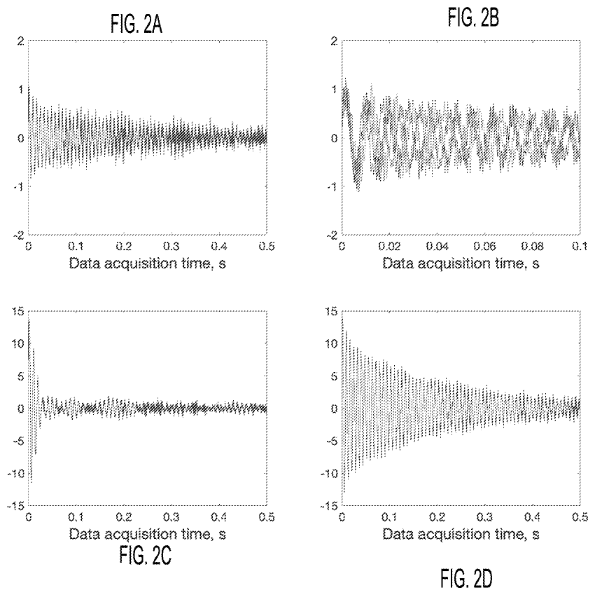

FIG. 2A illustrates the time-domain signals of FIG. 1A. FIG. 2B illustrates the time-domain signals of FIG. 1B. At short times (e.g., less than 0.01 second), all four signals can be overlapping, which can be indicative of the same phases. At later times (e.g., larger than 0.01 second), the phases of the signals can start to differ. FIG. 2C illustrates the time-domain signals of FIG. 1C. This shows the sum of all sixteen signals which decays rapidly (e.g., less than 0.05 seconds) corresponding to the broader linewidth as shown in FIG. 2C. FIG. 2D illustrates the time-domain signals of FIG. 1D. This shows the sum of all sixteen signals after the frequency correction which decays slowly similar to FIG. 2A. This corresponds to a narrow linewidth as shown in FIG. 2D.

The methods of the present disclosure can include denoting that the signal of the first scan is S(t), and its frequency spectrum is F(ω). S₁(t) can be given by Equation 10:

$${S}_{1} ( t ) = {{\int }_{- ∞}}^{+ ∞} d ω F ( ω ) exp ( - i ω t ) \qquad ( 10 )$$

Here, ω is the angular velocity (or angular frequency) and the frequency is defined as f=ω/2π. This relationship is called Fourier transformation. The Larmor frequency of hydrogen, in water for example, is proportional to the applied magnetic field, β₀, according to Equation 11:

$${f}_{L} = γ {B}_{0} ( 1 + CS ) \qquad ( 11 )$$

γ is the gyromagnetic ratio of the nucleus. For hydrogen, γ=42.57 MHz/T. At a subsequent scan when the magnetic field is shifted by a small amount, δB₀, the Larmor frequency is changed to

$${f}_{L}^{′} ,$$

according to Equation 12:

$${f}_{L}^{′} = γ ( {B}_{0} + δ {B}_{0} ) ( 1 + CS ) \qquad ( 12 )$$

Thus, the net frequency shift is given by Equation 13:

$$δ {f}_{L} \approx γδ {B}_{0} \qquad ( 13 )$$

Here, the chemical shift contribution to the frequency shift can be neglected since it is very small. Thus, the effect of the magnetic field drift can be to shift the NMR spectrum by a constant amount γδB₀ for all resonance peaks. As a result, if this frequency shift can be determined for each subsequent scan and this frequency shift can be corrected to the data, the frequency drift problem can be resolved, and the high-resolution spectrum can be recovered.

The method can include acquiring all the scans and storing them separately (e.g., not summing them) for further processing. The signal can be labeled as Sᵢ for the i^{th} scan. For the scan i, the frequency shift is δfᵢ, the frequency correction can be applied by multiplying exp (i2πδfᵢ) to the i^{th} data. The final frequency corrected data can be obtained according to Equation 14:

$$S ( t ) = {\sum }_{i = 1}^{N} exp ( i 2 πδ {f}_{i} \cdot t ) \cdot {S}_{i} ( t ) \qquad ( 14 )$$

Here, N is the total number of scans, and t is the detection time of the signal. The scans can include a list of a few thousand data points equally spaced in time. The time spacing can be from 10 μs to 1 minute. In addition, NMR data processing procedures, such as baseline correction, line broadening multiplier, and phase correction, can also be applied to Equation 14.

The method can include finding (e.g., determining, calculating, obtaining, acquiring) the frequency shift parameter, δfᵢ, by maximizing the following objective function:

$$χ ( \{ δ {f}_{i} \} ) ≡ {\sum }_{j = 1}^{M} {\vert S ( {t}_{j} ) \vert}^{2} \qquad ( 15 )$$

Here, {δfᵢ} represents the frequency shifts for all scans. The result of the maximization can be the values of the frequency shift for all scans. Once these values are obtained, all signals (Sᵢ) can be corrected for their frequency shift, and the high-resolution signal and spectrum can be obtained. This is demonstrated in FIG. 1D where the optimization result determines the frequency shift for every scan and the sum of the frequency-corrected spectrum is shown in FIG. 1D demonstrating a narrow signal peak and a much-improved signal-to-noise ratio.

The summation of data points can be performed from the first data point, j=1 to the M^{th} data point (j=M) as shown in Equation 15. This summation limits can be adjusted based on the condition of the data. For example, the first data point (j=1) can be corrupted during the data acquisition due to the limited circuit bandwidth and the receiver electronics. In this case, the data summation can start from the second, third, or other data points. Similarly, the last data point of the summation (M) can be chosen to be the last data point acquired or less. For example, if the signal decays to the noise floor before the end of the signal, the last section of the data can be only noise and may not be included in the data summation. In this case, data with signal-to-noise ratio of larger than 2, or 10 can be included for the data summation. Furthermore, the exponent in Equation 15 can use values other than 2, for example, 3, or 4, or 6.

Many maximization and/or optimization algorithms can be used. The algorithms can include, for example, Levenberg-Marquardt algorithm, Newton method, Quasi-Newton method, and gradient descent. Unconstrained optimization can be used. Constraint optimization can also be used to limit the range of the frequency shift during the optimization.

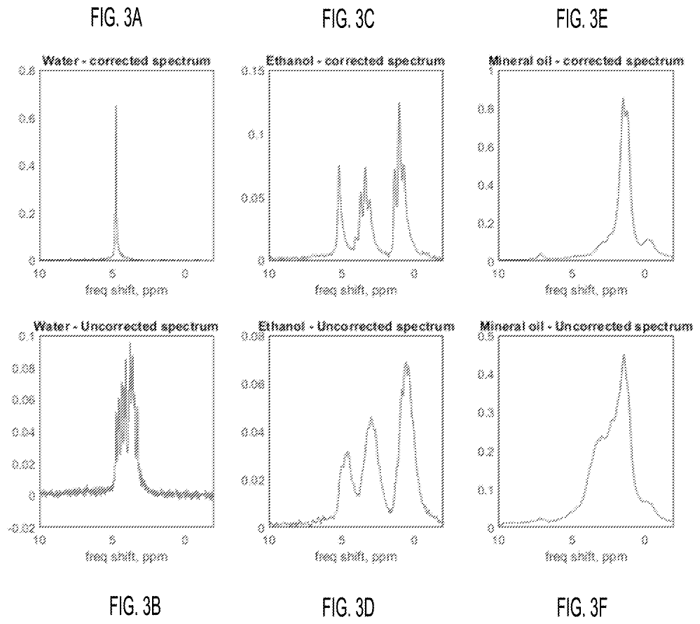

In addition to the objective function in Equation 15, which is an integration of the time-domain signal, the objective function can also be defined as an integral in the frequency domain according to Equation 16:

$${χ}_{ω} ( \{ δ {f}_{i} \} ) ≡ {{\int }^{{ω}^{+}}}_{ω = {ω}^{-}} d ω {\vert F ( ω ) \vert}^{2} \qquad ( 16 )$$

where ω⁻ and ω⁺ are the integration limits. The integration limits can cover the frequency range with the relevant spectral features. Examples of the data processed by the above algorithms (e.g., frequency correction, frequency correction of the present disclosure) are shown in FIGS. 3A, 3C, and 3E. Furthermore, the exponent in Equation 16 can use values other than 2, for example, 3, 4 or 6.

FIG. 3A illustrates the spectrum of water after frequency correction was applied. FIG. 3B illustrates the spectrum of water before frequency correction was applied. The corrected spectrum of FIG. 3A exhibits better resolution than the uncorrected spectrum of FIG. 3B. FIG. 3C illustrates the spectrum of ethanol after frequency correction was applied. FIG. 3D illustrates the spectrum of ethanol before frequency correction was applied. The corrected spectrum of FIG. 3C exhibits better resolution than the uncorrected spectrum of FIG. 3D. FIG. 3E illustrates the spectrum of mineral oil after frequency correction was applied. FIG. 3F illustrates the spectrum of mineral oil before frequency correction was applied. The corrected spectrum of FIG. 3E exhibits better resolution than the uncorrected spectrum of FIG. 3F.

The data can be processed in a pair-wise fashion (e.g., pair-wise optimization) for large frequency shifts by performing frequency correction of the first scan data with one other scan. When this pair-wise processing is finished for all scans, all of the scans can be brought to the vicinity of the frequency of the first scan. Then, the algorithm can be further applied to all the data after the pairwise processing.

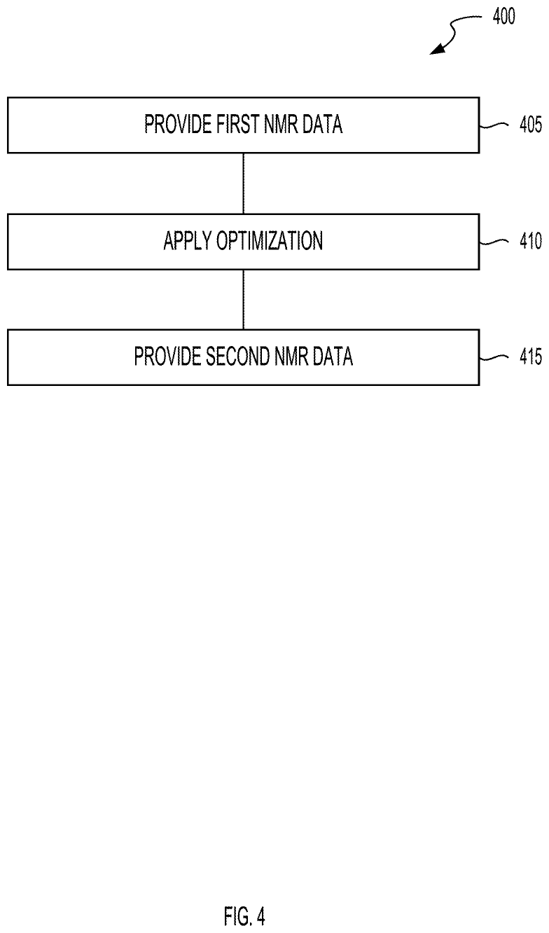

FIG. 4 illustrates a method 400 of improving NMR spectral resolution. The method 400 can include a method of NMR spectroscopy to obtain high or improved spectral resolution. In brief summary, the method 400 can include providing first NMR data (BLOCK 405). The method 400 can include applying optimization (BLOCK 410). The method 400 can include providing second NMR data (BLOCK 415).

The method 400 can include providing first NMR data (BLOCK 405). The first NMR data can include a plurality of NMR scans. The plurality of NMR scans can include a plurality of NMR spectra. The plurality of NMR scans can include a first NMR scan. The first NMR scan can have a first signal-to-noise ratio greater than 2. The first NMR scan can include a first NMR spectrum. The plurality of NMR scans can include a second NMR scan. The second NMR scan can have a second signal-to-noise ratio greater than 2. The second NMR scan can include a second NMR spectrum. The plurality of NMR scans can include a third NMR scan. The third NMR scan can have a third signal-to-noise ratio greater than 2. The third NMR scan can include a third NMR spectrum. The plurality of NMR scans can include greater than or equal to two NMR scans (e.g., 2 NMR scans, 3 NMR scans, 4 NMR scans, 8 NMR scans, 16 NMR scans, etc.). The first NMR data can have a first spectral resolution. The first spectral resolution can be quantified by quantifying the sharpness (e.g., degree of closeness or spread) of the one or more peaks of the spectrum. For instance, multiple peaks that are characterized by a narrower spread (e.g., located closely together or substantially overlapping with each other) would have a higher spectral resolution than if characterized by a wider spread (e.g., the peaks are more distanced or have a lower degree of overlap with each other). The first NMR data can be obtained from 1-dimensional experiments or multi-dimensional experiments. For example, the first NMR data can be obtained from 1-dimensional experiments or multi-dimensional experiments for the measurement of spectroscopy, relaxation, diffusion, or a combination thereof.

The method 400 can include applying optimization (BLOCK 410). For example, the method 400 can include applying optimization to the plurality of NMR scans. The optimization can include the use of at least one of Levenberg-Marquardt algorithm, Newton's method, a quasi-Newton method, or gradient descent. The optimization can include constrained (e.g., constraint) optimization or unconstrained optimization. Constrained optimization can include the process of optimizing a function (e.g., objective function) with respect to some variables in the presence of constraints on those variables. The variables can take on certain values within a larger range. Unconstrained optimization can include finding the maximum or minimum of a function (e.g., differentiable function) of several variables. The variables can have any value. The optimization can include pair-wise optimization.

The method 400 can include applying optimization to the plurality of NMR scans to obtain a frequency shift parameter. The parameter can include a value, level, extent, or indication of the frequency shift (e.g., frequency change, frequency delta, frequency offset). The frequency shift parameter can include a first frequency shift associated with the first NMR scan. The first frequency shift can be caused by a temperature shift of at least one of a magnet, environment, or equipment. The frequency shift parameter can include a second frequency shift associated with the second NMR scan. The second frequency shift can be caused by a temperature shift (e.g., change, variation, deviation) of at least one of a magnet, environment, or equipment. The frequency shift parameter can include a third frequency shift associated with the third NMR scan. The third frequency shift can be caused by a temperature shift of at least one of a magnet, environment, or equipment. Obtaining the frequency shift parameter can include maximizing a function of the second NMR data. Obtaining the

$${\sum }_{j = 1}^{M} {\vert S ( {t}_{j} ) \vert}^{2} ,$$

frequency shift parameter can include maximizing where S (ti) is associated with the second NMR data, and M is a number of data points used in the summation. M can include a number of scans. Obtaining the frequency shift parameter can include integrating a function of a time-domain signal. The time-domain (e.g., time domain) can include analysis of a functions or signals with respect to time. The time-domain signal can include a signal represented over time. Examples of time-domain signals can include the signals shown in FIGS. 2A-2D. Obtaining the frequency shift parameter can include maximizing

$${\int }_{ω = {ω}^{-}}^{{ω}^{+}} d ω {\vert F ( ω ) \vert}^{2} ,$$

wherein F(ω) is associated with the second NMR data. Obtaining the frequency shift parameter can include integrating a function of a frequency-domain signal. The frequency-domain (e.g., frequency domain) can include analysis of a functions or signals with respect to frequency. The frequency-domain signal can include a signal represented over frequency. Examples of frequency-domain signals can include the signals shown in FIGS. 1A-1D. The frequency-domain signal can be represented by F(ω).

The method 400 can include providing second NMR data (BLOCK 415). The second NMR data can include the first NMR scan shifted by the first frequency shift. The second NMR data can include the second NMR scan shifted by the second frequency shift. The second NMR data can include the third NMR scan shifted by the third frequency shift. The second NMR data can have a second spectral resolution. The second spectral resolution can be greater than the first spectral resolution. The first spectral resolution can be less than the second spectral resolution. The second spectral resolution can be quantified by quantifying the sharpness of the one or more peaks of the spectrum. The second NMR data can be combined by summing all scans of the second NMR data to provide improved signal-to-noise data. For example, the second NMR data can be combined by summing the first NMR scan shifted by the first frequency shift and the second NMR scan shifted by the second frequency shift.

The method 400 can include performing an NMR experiment on a sample. For example, the method 400 can include performing the NMR experiment on the sample to obtain the first NMR data. The first NMR data can be acquired over time. The method 400 can include storing the data from each scan separately. For example, the first NMR scan can be stored separately from the second NMR scan. The second NMR scan can be stored separately from the third NMR scan. The third NMR scan can be stored separately from the first NMR scan. The method 400 can include applying a numerical optimization algorithm to the first NMR data to obtain the frequency shift associated with each scan. The method 400 can include applying the obtained frequency shift to improve the spectral resolution of the first NMR data.

A non-transitory computer-readable media can have computer-readable instructions stored thereon that, when executed by at least one controller, cause the at least one controller to provide the first nuclear magnetic resonance data. The first nuclear magnetic resonance data can include the plurality of NMR scans. The first nuclear magnetic resonance data can have the first spectral resolution. The plurality of NMR scans can include the first NMR scan and the second NMR scan. The instructions can cause the at least one controller to apply optimization to the plurality of NMR scans to obtain the frequency shift parameter. The frequency shift parameter can include the first frequency shift associated with the first NMR scan and the second frequency shift associated with the second NMR scan. The instructions can cause the at least one controller to provide second NMR data. The second NMR data can include the first NMR scan shifted by the first frequency shift and the second NMR scan shifted by the second frequency shift. The second NMR data can have the second spectral resolution greater than the first spectral resolution.

In some embodiments, the plurality of NMR scans can include the third NMR scan. The frequency shift parameter can include the third frequency shift associated with the third NMR scan. The second NMR data can include the third NMR scan shifted by the third frequency shift. In some embodiments, the optimization includes use of at least one of Levenberg-Marquardt algorithm, Newton's method, a quasi-Newton method, or gradient descent. The optimization can include constrained optimization. The optimization can include unconstrained optimization. The optimization can include pair-wise optimization.

In some embodiments, obtaining the frequency shift parameter includes maximizing a function of the second NMR data. Obtaining the frequency shift parameter can include maximizing

$${\sum }_{j = 1}^{M} {\vert S ( {t}_{j} ) \vert}^{2} ,$$

where S(tⱼ) is associated with the second NMR data, and M is a number of scans. Obtaining the frequency shift parameter can include integrating the function of the time-domain signal. Obtaining the frequency shift parameter can include maximizing

$${\int }_{ω = {ω}^{-}}^{{ω}^{+}} d ω {\vert F ( ω ) \vert}^{2} .$$

F(ω) can be associated with the second NMR data. Obtaining the frequency shift parameter can include integrating a function of a frequency-domain signal.

In some embodiments, the first NMR scan has a first signal-to-noise ratio greater than 2 and the second NMR scan has a second signal-to-noise ratio greater than 2. The first NMR data can be obtained from 1-dimensional experiments or multi-dimensional experiments. The first frequency shift and the second frequency shift can be caused by a temperature shift of at least one of a magnet, environment, or equipment. The second NMR data can be combined by summing all the scans of the second NMR data to provide improved signal-to-noise data.

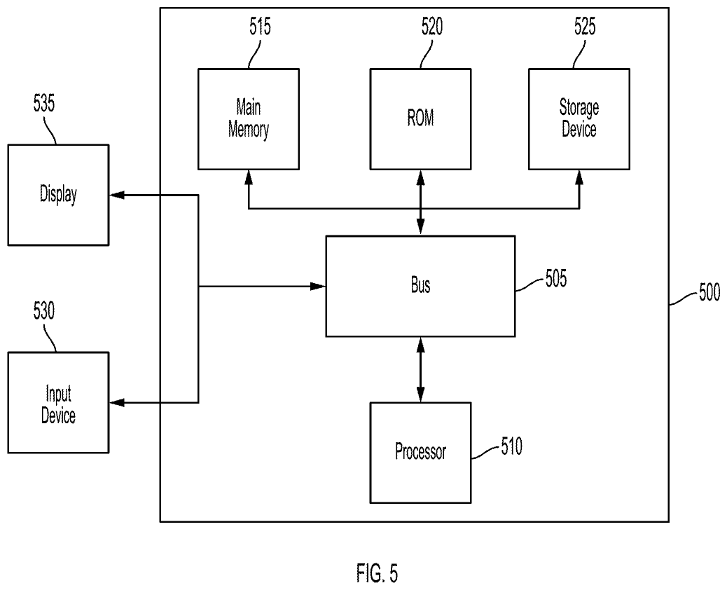

FIG. 5 depicts an example block diagram of an example computer system 500 (e.g., computing device). The system 500 can be included with or part of the at least one controller. The computer system 500 can include or be used to implement a data processing system or its components. The computing system 500 includes at least one bus 505 or other communication component for communicating information and at least one processor 510 or processing circuit coupled to the bus 505 for processing information. The processor 510 can be part of the controller. The computing system 500 can also include one or more processors 510 or processing circuits coupled to the bus for processing information. The computing system 500 also includes at least one main memory 515 (e.g., of the controller), such as a random-access memory (RAM) or other dynamic storage device, coupled to the bus 505 for storing information, and instructions to be executed by the processor 510. The main memory 515 can be used for storing information during execution of instructions by the processor 510. The computing system 500 may further include at least one read only memory (ROM) 520 or other static storage device coupled to the bus 505 for storing static information and instructions for the processor 510. A storage device 525, such as a solid-state device, magnetic disk or optical disk, can be coupled to the bus 505 to persistently store information and instructions.

The computing system 500 may be coupled via the bus 505 to a display 535, such as a liquid crystal display, or active-matrix display, for displaying information to a user. An input device 530, such as a keyboard or voice interface may be coupled to the bus 505 for communicating information and commands to the processor 510. The input device 530 can include a touch screen display 535. The input device 530 can also include a cursor control, such as a mouse, a trackball, or cursor direction keys, for communicating direction information and command selections to the processor 510 and for controlling cursor movement on the display 535.

The processes, systems and methods described herein can be implemented by the computing system 500 in response to the processor 510 executing an arrangement of instructions contained in main memory 515. Such instructions can be read into main memory 515 from another computer-readable medium, such as the storage device 525. Execution of the arrangement of instructions contained in main memory 515 causes the computing system 500 to perform the illustrative processes described herein. One or more processors in a multi-processing arrangement may also be employed to execute the instructions contained in main memory 515. Hard-wired circuitry can be used in place of or in combination with software instructions together with the systems and methods described herein. Systems and methods described herein are not limited to any specific combination of hardware circuitry and software. The computing system 500 can have sensors (e.g., sensor 130) that feed data. The computing system 500 can have the ability for data to be sent or passed to connected units and sensors. The computing system 500 can pull data from connected units and sensors.

Although an example computing system has been described in FIG. 5, the subject matter including the operations described in this specification can be implemented in other types of digital electronic circuitry, or in computer software, firmware, or hardware, including the structures disclosed in this specification and their structural equivalents, or in combinations of one or more of them.

Embodiments of the subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatus. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium may not be a propagated signal, a computer storage medium can be a source or destination of computer program instructions encoded in an artificially generated propagated signal. The computer storage medium can also be, or be included in, one or more separate components or media (e.g., multiple CDs, disks, or other storage devices).

The operations described in this specification can be performed by a data processing apparatus on data stored on one or more computer-readable storage devices or received from other sources. The term “data processing apparatus” or “computing device” encompasses various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a circuit, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more circuits, subprograms, or portions of code). A computer program can be deployed to be executed on one computer or on multiple computers that are located at one site or distributed across multiple sites and interconnected by a communication network.

Processors suitable for the execution of a computer program include, by way of example, microprocessors, and any one or more processors of a digital computer. A processor can receive instructions and data from a read-only memory or a random access memory or both. The elements of a computer are a processor for performing actions in accordance with instructions and one or more memory devices for storing instructions and data. A computer can include, or be operatively coupled to receive data from or transfer data to, or both, one or more mass storage devices for storing data, e.g., magnetic, magneto optical disks, or optical disks. A computer need not have such devices. Moreover, a computer can be embedded in another device, e.g., a personal digital assistant (PDA), a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

The implementations described herein can be implemented in any of numerous ways including, for example, using hardware, software or a combination thereof. When implemented in software, the software code can be executed on any suitable processor or collection of processors, whether provided in a single computer or distributed among multiple computers.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

A computer employed to implement at least a portion of the functionality described herein may comprise a memory, one or more processing units (also referred to herein simply as “processors”), one or more communication interfaces, one or more display units, and one or more user input devices. The memory may comprise any computer-readable media, and may store computer instructions (also referred to herein as “processor-executable instructions”) for implementing the various functionalities described herein. The processing unit(s) may be used to execute the instructions. The communication interface(s) may be coupled to a wired or wireless network, bus, or other communication means and may therefore allow the computer to transmit communications to or receive communications from other devices. The display unit(s) may be provided, for example, to allow a user to view various information in connection with execution of the instructions. The user input device(s) may be provided, for example, to allow the user to make manual adjustments, make selections, enter data or various other information, or interact in any of a variety of manners with the processor during execution of the instructions.

The various methods or processes outlined herein may be coded as software that is executable on one or more processors that employ any one of a variety of operating systems or platforms. Additionally, such software may be written using any of a number of suitable programming languages or programming or scripting tools, and also may be compiled as executable machine language code or intermediate code that is executed on a framework or virtual machine.

In this respect, various inventive concepts may be embodied as a computer-readable storage medium (or multiple computer-readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the solution discussed above. The computer-readable medium or media can be transportable, such that the program or programs stored thereon can be loaded onto one or more different computers or other processors to implement various aspects of the present solution as discussed above.

The terms “program” or “software” are used herein to refer to any type of computer code or set of computer-executable instructions that can be employed to program a computer or other processor to implement various aspects of embodiments as discussed above. One or more computer programs that when executed perform methods of the present solution need not reside on a single computer or processor, but may be distributed in a modular fashion amongst a number of different computers or processors to implement various aspects of the present solution.

Computer-executable instructions may be in many forms, such as program modules, executed by one or more computers or other devices. Program modules can include routines, programs, objects, components, data structures, or other components that perform particular tasks or implement particular abstract data types. The functionality of the program modules can be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementations,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Elements other than ‘A’ and ‘B’ can also be included.

The systems and methods described herein may be embodied in other specific forms without departing from the characteristics thereof. The foregoing implementations are illustrative rather than limiting of the described systems and methods.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

1. A method, comprising:
providing first nuclear magnetic resonance (NMR) data comprising a plurality of NMR scans and having a first spectral resolution, the plurality of NMR scans comprising a first NMR scan and a second NMR scan;
applying optimization to the plurality of NMR scans to obtain a frequency shift parameter comprising a first frequency shift associated with the first NMR scan and a second frequency shift associated with the second NMR scan; and
providing second NMR data comprising the first NMR scan shifted by the first frequency shift and the second NMR scan shifted by the second frequency shift, the second NMR data having a second spectral resolution greater than the first spectral resolution.

2. The method of claim 1, wherein:
the plurality of NMR scans comprises a third NMR scan;
the frequency shift parameter comprises a third frequency shift associated with the third NMR scan; and
the second NMR data comprises the third NMR scan shifted by the third frequency shift.

3. The method of claim 1, wherein the optimization includes use of at least one of: Levenberg-Marquardt algorithm, Newton's method, a quasi-Newton method, or gradient descent.

4. The method of claim 1, wherein obtaining the frequency shift parameter includes maximizing a function of the second NMR data.

5. The method of claim 1, wherein obtaining the frequency shift parameter includes maximizing
$${\sum }_{j = 1}^{M} {\vert S ( {t}_{j} ) \vert}^{2} ,$$
wherein S(tⱼ) is associated with the second NMR data, and M is a number of scans.

6. The method of claim 1, wherein obtaining the frequency shift parameter includes integrating a function of a time-domain signal.

7. The method of claim 1, wherein obtaining the frequency shift parameter includes maximizing
$${\int }_{ω = {ω}^{-}}^{{ω}^{+}} d ω {\vert F ( ω ) \vert}^{2} ,$$
wherein F(ω) is associated with the second NMR data.

8. The method of claim 1, wherein obtaining the frequency shift parameter includes integrating a function of a frequency-domain signal.

9. The method of claim 1, wherein the first NMR scan has a first signal-to-noise ratio greater than 2 and the second NMR scan has a second signal-to-noise ratio greater than 2.

10. The method of claim 1, wherein the optimization includes constrained optimization.

11. The method of claim 1, wherein the optimization includes unconstrained optimization.

12. The method of claim 1, wherein the optimization includes pair-wise optimization.

13. The method of claim 1, wherein the first NMR data is obtained from 1-dimensional experiments or multi-dimensional experiments.

14. The method of claim 1, wherein the first frequency shift and the second frequency shift are caused by a temperature shift of at least one of a magnet, environment, or equipment.

15. The method of claim 1, wherein the second NMR data is combined by summing all scans of the second NMR data to provide improved signal-to-noise data.

16. A non-transitory computer-readable media having computer-readable instructions stored thereon that, when executed by at least one controller, cause the at least one controller to:
provide first nuclear magnetic resonance (NMR) data comprising a plurality of NMR scans and having a first spectral resolution, the plurality of NMR scans comprising a first NMR scan and a second NMR scan;
apply optimization to the plurality of NMR scans to obtain a frequency shift parameter comprising a first frequency shift associated with the first NMR scan and a second frequency shift associated with the second NMR scan; and
provide second NMR data comprising the first NMR scan shifted by the first frequency shift and the second NMR scan shifted by the second frequency shift, the second NMR data having a second spectral resolution greater than the first spectral resolution.

17. The non-transitory computer-readable media of claim 16, wherein:
the plurality of NMR scans comprises a third NMR scan;
the frequency shift parameter comprises a third frequency shift associated with the third NMR scan; and
the second NMR data comprises the third NMR scan shifted by the third frequency shift.

18. The non-transitory computer-readable media of claim 16, wherein the optimization includes use of at least one of: Levenberg-Marquardt algorithm, Newton's method, a quasi-Newton method, or gradient descent.

19. The non-transitory computer-readable media of claim 16, wherein obtaining the frequency shift parameter includes maximizing a function of the second NMR data.

20. The non-transitory computer-readable media of claim 16, wherein obtaining the frequency shift parameter includes maximizing
$${\sum }_{j = 1}^{M} {\vert S ( {t}_{j} ) \vert}^{2} ,$$
wherein S′(tⱼ) is associated with the second NMR data, and M is a number of scans.
